(19) United States
(12) Patent Application Publication
(10) Pub. No.: US 2002/0135270 A1
(43) Pub. Date: Sep. 26, 2002

(54) Acoustic wave device comprising alternating polarisation domains

(76) Inventors: Sylvain Ballandras, Avanne-Aveney (FR); Brice Gautier, Montbeliard (FR); Daniel Hauden, Besancon (FR); Jean-Claude Labrune, Chatenois-Les-Forges (FR)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 10/070,904

(22) PCT Filed: Jul. 10, 2001
(86) PCT No.: PCT/FR01/02225

(30) Foreign Application Priority Data
Jul. 13, 2000 (FR) 00/09246

(51) Int. Cl. H03H 9/25

(52) U.S. Cl. 310/313 R

(57) ABSTRACT

The invention relates to an acoustic wave device comprising a layer of ferroelectric material (C) and a substrate (S), characterized in that the layer of ferroelectric material lies between a first electrode (E₁) which is deposited on the surface of the substrate or is a constituent part of the substrate and a second electrode (E₂) and in that the layer of ferromagnetic material comprises positive first polarization domains (D₁) and negative second polarization domains (D₂)

For applications in the field of surface wave transducers, it may be advantageous to produce structures with domain inversion with a pitch of the order of a few hundred nanometers, said structures being suitable for applications at high frequencies (of the order of 1 gigahertz).

The field of the invention is that of acoustic wave devices and especially the field of surface wave transducers able to operate at very high frequencies of the order of several gigahertz.

Conventionally, transducers are manufactured at the present time using comb structures based on interdigitated electrodes, using structures consisting of two, four or eight electrodes per wavelength λ, λ corresponding to the central operating frequency of the transducer, depending on the intended applications. In all these transduces, the generally used ratio of the area of the metallized surfaces on the substrate to the area of the free surfaces is typically between 0.25 and 0.75.

A new class of transducers has nevertheless come to light. These are so-called small-gap transducers in which the free surface is very small so as to obtain the smallest possible distance between two consecutive electrodes. The advantages of this type of transducer stem from the fact that it is possible to obtain the largest possible electrode widths per period with greatly reduced inter-electrode reflection phenomena.

The drawback with these structures stems from the technological difficulties. As an example, for a transducer operating at 1.6 GHz, electrodes of λ/2, i.e. 1.5 μm, in width must be separated by a distance of the order of a few hundred angstroms, which requires very tricky technology.

Moreover, when power is sent into electrodes very closely spaced apart, the constituent metal of said electrodes, in this case aluminum (most often used), converts energy into heat and has a tendency to creep, in this way possibly short-circuiting the various electrodes (in the case of Rayleigh waves).

To solve these various problems, the invention provides an acoustic wave device having continuous electrodes made of a polarization-inverting ferroelectric material.

More specifically, the subject of the invention is an acoustic wave device comprising a layer of ferroelectric material and a substrate, characterized in that the layer of ferroelectric material lies between a first electrode which is deposited on the surface of the substrate or is a constituent part of the substrate and a second electrode and in that the layer of ferromagnetic material comprises positive first polarization domains and negative second polarization domains.

According to a first variant, the second electrode is deposited on the layer of ferromagnetic material. According to a second variant, the second electrode is supported by a cover, so as to create a space between said second electrode and the layer of ferroelectric material and thereby increase the propagation characteristics of the surface waves, which are less constrained because of no contact between the ferroelectric material and the upper electrode.

According to a variant of the invention, the layer of ferroelectric material may also comprise nonpolarized domains which can introduce phase elements in order to influence the directionality of the acoustic waves propagating in the layer of ferroelectric material, as will be explained later.

According to a variant of the invention, the acoustic wave device comprises a series of linear domains of positive, negative or zero polarization.

According to another variant of the invention, the domains are distributed in two orthogonal directions, which favors combinations of interference between acoustic waves and allows an additional degree of freedom in order to produce special transducer structures.

According to a variant of the invention, the acoustic wave device comprises at least one electrode whose surface is defined by two parameters y and x satisfying an equation of the type y f(x) where f is a real function.

According to a variant of the invention, the spatial polarization distribution in the plane of the layer of ferroelectric material follows a geometrical law so that the resulting polarized surface is defined by two parameters y and x, f being a real function.

The invention will be more clearly understood and further advantages will become apparent on reading the description which follows, given by way of nonlimiting example, and from the appended figures in which:

FIG. 1 illustrates a process for creating positive polarization domains and negative polarization domains for a surface wave device according to the invention;

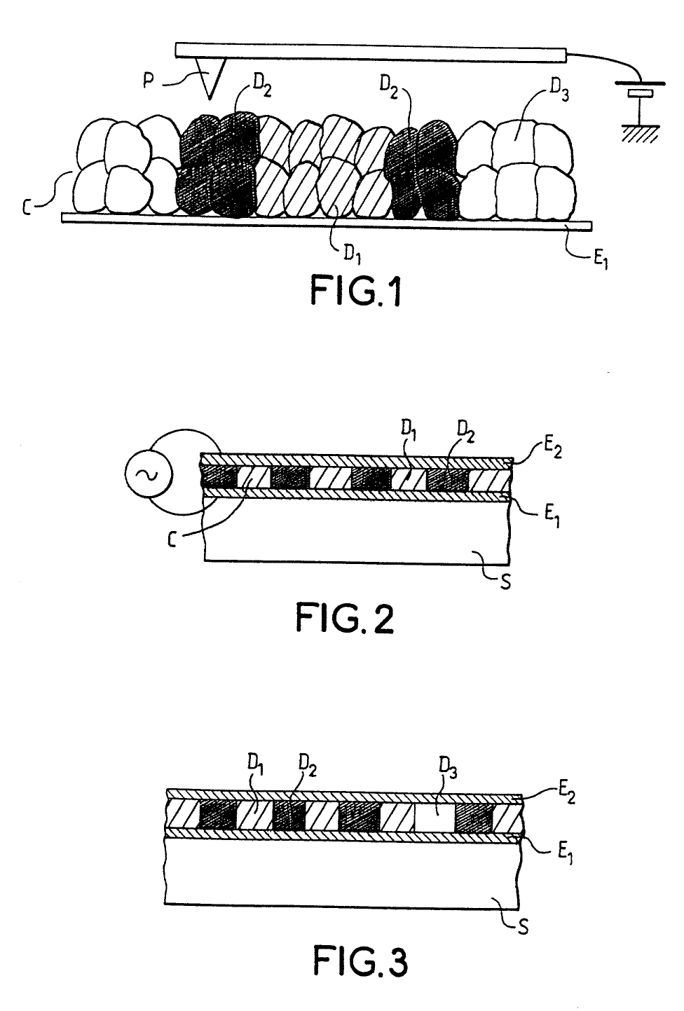

FIG. 2 illustrates a first example of a surface wave device according to the invention;

FIG. 3 illustrates an example of a device according to the invention having nonpolarized domains;

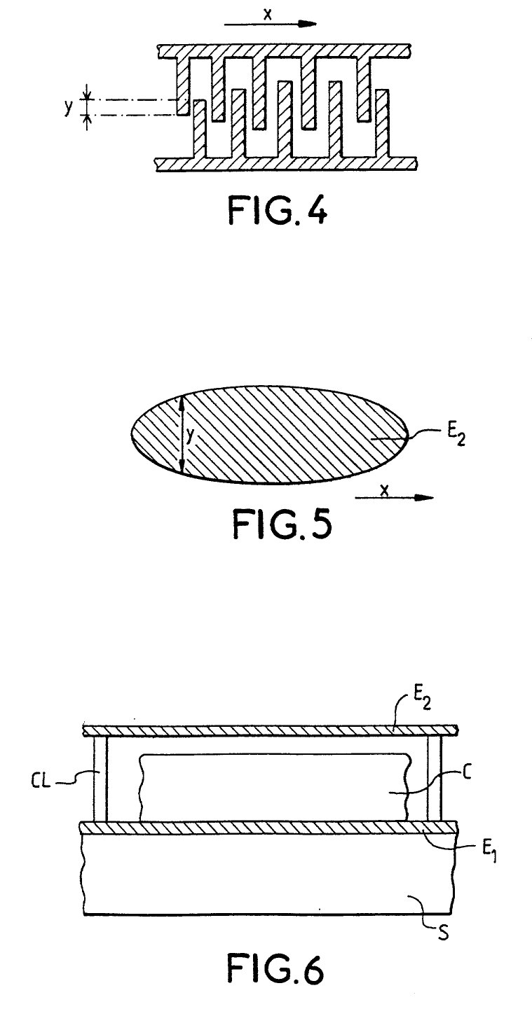

FIG. 4 illustrates an interdigitated electrode architecture according to the prior art known for creating an apodization function;

FIG. 5 illustrates an example of a form of electrodes used in the invention to produce an apodization function; and

FIG. 6 illustrates a second example of a surface-wave device using a second electrode which is not in contact with the layer of ferroelectric material.

In general, the invention provides an acoustic wave device using a layer of ferroelectric material in which domains of alternating polarizations are produced.

Specifically, it has been proposed to create locally polarized domains and to benefit from this kind of local polarization in order to functionalize, or make periodic, the electroacoustic properties of the resulting material so as to manufacture acoustic wave devices which are piezoelectrically excited by means of a ferroelectric material on any type of metal substrate or metallized surface thanks to a local electric polarization.

To do this, a layer of ferroelectric material is conventionally produced on the surface of a metal substrate or on the surface of a metallized substrate. Typically, this may be any monocrystalline, polycrystalline or multicrystalline ferroelectric material, for example lead titanium zirconium oxide (PZT), LiNbO₃, LiTaO₃ or else KNbO₃. Typically, the layer may have a thickness of less than about 10 μm. The material (prepolarized or not) is then subjected locally to a large electric field, especially by means of a metal electrode in the form of a tip or apex, or one in which the geometry has been made according to the desired local polarization profile.

The purpose of this operation is to exceed the coercive field of the material for a sufficient time, greater than the minimum specific polarization time of the material. In this way, the molecular dipoles of the ferroelectric material are durably aligned so as to obtain a controlled piezoelectric polarization. This is because the polarity of the electric field thus applied makes it possible for the direction of polarization of the ferroelectric material to be imposed locally. During application of the electric field, the subjacent electrode or the substrate itself, depending on the case, is raised to the electrical reference. FIG. 1 illustrates this process for creating positive first polarization domains D₁ and negative second polarization domains D₂ and for keeping unpolarized third domains D₃ within the layer C of ferroelectric material on the surface of a substrate S covered with a first electrode E₁. A tip P is positioned opposite said layer C.

We will now describe this process in the case of a PZT oxide layer. Typically, the first electrode, made of a platinum/titanium alloy capable of withstanding the temperatures for producing the PZT ceramic (temperatures greater than about 500° C.), is produced on a substrate composed of a material of the type consisting of silicon, sapphire, glass, etc. The PZT layer is produced by deposition of the sputtering or sol-gel type so as to obtain a layer having a thickness of the order of a few microns. A tip is then used, such as those used for near-field microscopes of the atomic force microscope type in which a tip is brought sufficiently close to the specimen so as to be sensitive to the van der Waals' forces (AFM) or of the tunnel microscope type in which a tip is brought sufficiently close to the specimen to allow electrons to transfer from the specimen to the tip by an electron tunneling effect (STM). By applying a potential to the tip, the expected forced polarization is obtained in a precise and reproducible manner. For very thin PZT layers, of the order of 500 nm in thickness, potentials of 5 to 12 V are enough to generate fields greater than the coercive field. In practice, the size of the domains thus created may be less than 130 nm.

It is possible to apply the process to a region of greater or lesser width according to the fineness of the tip. In the case of PZT, the spatial resolution of the domain inversion depends directly on the size of the material grain. In layers deposited by sputtering, the grain size may typically be of the order of a few hundred nanometers and of the order of about 60 nm in the case of grains obtained by the sol-gel process.

For applications in the field of surface wave transducers, it is thus possible to produce structures with domain inversion with a pitch of the order of a few hundred nanometers, and therefore structures very suitable for high-frequency applications. This is because, according to the invention, the pitch of the grating is of the order of the acoustic wavelength. The frequency is obtained to a first approximation by dividing the phase velocity of the wave by the pitch of the grating. In the case of conventional surface wave devices, the grating pitch used is generally equal to one half of the acoustic wavelength.

The acoustic wave devices according to the invention, using polarization inversion in a ferroelectric material, may advantageously be surface wave devices.

This is because, by covering the layer of ferroelectric material with a second electrode, the structure thus produced may be excited dynamically.

By alternating the positive polarization and negative polarization domains, the matter within the layer of ferromagnetic material undergoes alternating extensions and compression so as to generate constructive acoustic interference, preferably propagating in the plane of the layer (and thus having a guide function) rather than in the volume. This is because the speed of propagation of guided elastic waves in the layer is less than the speed of propagation of elastic waves in the substrate. FIG. 2 shows an example of a device according to the invention, comprising a substrate S, a layer C of ferroelectric material having first domains D₁ and second domains D₂, and a second electrode E₂ deposited on the surface of the layer C, the electrical excitation taking place by means of the electrodes E₁ and E₂. It is therefore possible to define on the surface of the substrate a single transducer, which has a well-defined characteristic admittance, used in combination with other transducers of the same type (but whose central frequency is different) so as to produce lattice filters or ladder filters, or else to define an input transducer and an output transducer.

According to this inventive concept, it is possible to produce transduction functions very directly, allowing transducers to be made up with given specifications.

The period of the domains D₁ and D₂ is then equivalent to the period between electrodes of the same polarity within the interdigitated structures of the prior art.

In particular, it is possible to influence the directionality of the surface acoustic waves by creating, from the polarization standpoint, neutral elements which modify the phase of the waves locally disturbing the pitch of the alternating domains, as illustrated in FIG. 3. This is because by locally creating a disturbance (domain D₃) in the alternating distribution of positive polarization domains (D₁) and negative polarization domains (D₂), the propagation of the surface acoustic waves is disturbed nonsymmetrically, privileging one direction rather than the other.

It is also possible to produce surface wave devices with highly wavelength-selective filtering functions more simply than in the prior art.

This is because, to produce surface wave devices with a high rejection, it is common practice to establish apodization functions by the overlapping of complex interdigitated electrodes, as illustrated in FIG. 4. The variable y represents the overlap length of two adjacent electrodes. It has been shown that a function of the type y=sinx/x allows a very steep filtering function to be obtained.

In general, the apodization function allows amplitude modulation of the elastic wave transmission in such a way that the pulse response of a structure having two opposed transducers, one of which is apodized and the other is not (but does have an acoustic aperture at least equal to the largest aperture of the apodized transducer), has an identical form to the apodization function. If the spatial apodization is triangular for example, by exciting the system with a Dirac function a signal is received which is triangular over time.

It is also possible in spontaneously unpolarized materials (for example thin-film PZT) to create the apodization function directly during the local polarization operation, by producing longer or shorter linear domains so as to reconstruct the desired function.

According to the invention, it is possible to simulate this type of overlap by the geometry of one of the electrodes of the acoustic wave device, as illustrated in FIG. 5.

In the first example of a device according to the invention, illustrated in FIG. 3, the second electrode is produced on the surface of the ferroelectric material.

FIG. 6 describes a second example of a surface wave device according to the invention, in which an excitation is created without any contact between the upper electrode and the layer of ferroelectric material. To do this, the electrode E₂ is supported by a cover CL resting on the substrate S. Typically, the thickness of this gap may be less than about twenty microns. Electric field lines are still present between two electrodes and therefore within the ferroelectric material. Such a structure has the following advantages:

the problems of the metallizations aging, at least at the upper electrode, are limited, as are the problems of power withstand of the metal layers and those of acoustic losses introduced by the thin-film metals.

With an architecture in which the cover can be removed, it also becomes possible to reconfigure the positive, negative or zero polarization domains and thus reprogram the acoustic wave device.

1. An acoustic wave device comprising a layer of ferroelectric material (C) and a substrate (S), characterized in that the layer of ferroelectric material lies between a first electrode (E₁) which is deposited on the surface of the substrate or is a constituent part of the substrate and a second electrode (E₂) and in that the layer of ferromagnetic material comprises positive first polarization domains (D₁) and negative second polarization domains (D₂).

2. The acoustic wave device as claimed in claim 1, characterized in that the second electrode is deposited on the surface of the layer of ferroelectric material.

3. The acoustic wave device as claimed in claim 1, characterized in that it includes a cover (CL) resting on the substrate, said cover having the second electrode, so as to create a space between said second electrode and the layer of ferroelectric material.

4. The surface wave device as claimed in claim 3, characterized in that the cover can be removed from the layer of ferroelectric material.

5. The acoustic wave device as claimed in one of claims 1 to 4, characterized in that it comprises unpolarized third domains (D₃) so as to influence the directivity of the acoustic waves.

6. The acoustic wave device as claimed in one of claims 1 to 5, characterized in that it comprises a series of linear domains having first domains and second domains.

7. The acoustic wave device as claimed in claim 6, characterized in that the series of linear domains furthermore includes unpolarized domains.

8. The acoustic wave device as claimed in one of claims 1 to 5, characterized in that it comprises a matrix arrangement of first domains and of second domains.

9. The acoustic wave device as claimed in claim 8, characterized in that it furthermore includes unpolarized domains.

10. The acoustic wave device as claimed in one of claims 1 to 9, characterized in that the ferroelectric material is lead titanium zirconium oxide.

11. The acoustic wave device as claimed in claim 10, characterized in that the first electrode is a platinum/titanium alloy.

12. The acoustic wave device as claimed in one of the preceding claims, characterized in that the substrate is made of silicon.

13. The acoustic wave device as claimed in one of the preceding claims, characterized in that the second electrode is made of aluminum.

14. The acoustic wave device as claimed in one of claims 10 to 13, characterized in that it comprises at least one electrode whose surface is defined by two parameters y and x satisfying an equation of the type y=f(x) where f is a real function.

15. The acoustic wave device as claimed in one of claims 10 to 13, characterized in that the spatial polarization distribution in the plane of the layer of ferroelectric material follows a geometrical law so that the resulting polarized surface is defined by two parameters y and x satisfying an equation of the type y=f(x) where f being a real function.

16. A process for manufacturing a surface wave device as claimed in one of claims 1 to 15, characterized in that it comprises the following steps:
production of a layer of ferroelectric material on the surface of a substrate having a first electrode;
formation in the layer of ferroelectric material of positive and negative polarization domains by applying an electric field greater than the coercive field of the ferroelectric material, the polarity of which determines the direction of polarization of the domains; and
production of a second electrode opposite the ferroelectric material.

17. The process for manufacturing an acoustic wave device as claimed in claim 16, characterized in that the second electrode is produced on the surface of the layer of ferroelectric material.

18. The process for manufacturing an acoustic wave device as claimed in claim 16, characterized in that the second electrode is supported by a cover fixed to the substrate.
